(19) United States
(12) Patent Application Publication
(10) Pub. No.: US 2022/0165588 A1
(43) Pub. Date: May 26, 2022

(54) SYSTEM FOR PROCESSING SUBSTRATE

(71) Applicant: EUGENE TECHNOLOGY CO., LTD., Yongin-Si (KR)

(72) Inventors: Chang Dol KIM, Yongin-Si (KR); Sung Min NAM, Yongin-Si (KR)

(21) Appl. No.: 17/522,897

(22) Filed: Nov. 9, 2021

(30) Foreign Application Priority Data
Nov. 24, 2020 (KR) 10-2020-0159061

(51) Int. Cl. H01L 21/67; H01L 21/673

(52) U.S. Cl. CPC H01L 21/67017; H01L 21/67303; H01L 21/67253

(57) ABSTRACT

Provided is a system for processing a substrate. The system for processing the substrate includes a process tube configured to provide a processing space for the substrate and an exhaust module connected to an exhaust port of the process tube to exhaust process residues within the processing space to the outside. The exhaust module includes an exhaust tube connected to the exhaust port, a sealing case configured to accommodate at least a portion of the exhaust tube, and a local exhaust part provided in the sealing case to exhaust the inside of the sealing case.

### CROSS-REFERENCE TO RELATED APPLICATION

This application claims priority to Korean Patent Application No. 10-2020-0159061 filed on Nov. 24, 2020, and all the benefits accruing therefrom under 35 U.S.C. § 119, the contents of which are incorporated by reference in their entirety.

### BACKGROUND

The present disclosure relates to a system for processing a substrate, and more particularly, to a system for processing a substrate, which prevents an exhaust gas exhausted through an exhaust tube from leaking to the outside.

In general, a substrate processing method is classified into single wafer type substrate processing method capable of processing one substrate and a batch type substrate processing method capable of processing a plurality of substrates at the same time. Such a single wafer type substrate processing apparatus has a simple structure, but has low productivity. Thus, the batch type substrate processing apparatus capable of being mass-producing substrates is widely used.

In a system for processing a substrate, chemicals may be used as a process gas for processing the substrate, and the chemicals may be toxic, flammable, corrosive, retardant, etc., and may be harmful to the human body.

In the system for processing the substrate in accordance with the related art, at least a portion of an exhaust tube for exhausting process residues of the process tube is exposed, and the process residues exhausted to the exhaust tube may also contain toxic chemicals. Thus, when the exhaust gas leaks to the exhaust tube, safety accidents may occur due to the chemical substances.

Particularly, a connection part such as an O-ring interposed for sealing a gap between an exhaust port and the exhaust tube of the process tube and/or between the exhaust tubes is deformed and/or damaged by prolonged use and/or heat, and thus leaking may occur, and the exhaust gas may leak through the gap.

When the exhaust gas leaks, not only the exhaust gas may be harmful to the human body, but also tens or hundreds of devices in a semiconductor manufacturing facility (FAB) have to be shut down.

### SUMMARY

The present disclosure provides a system for processing a substrate, which is capable of preventing an exhaust gas from leaking to the outside by casing an exhaust tube.

In accordance with an exemplary embodiment, a system for processing a substrate includes: a process tube configured to provide a processing space for the substrate; and an exhaust module connected to an exhaust port of the process tube to exhaust process residues within the processing space to the outside, wherein the exhaust module includes: an exhaust tube connected to the exhaust port; a sealing case configured to accommodate at least a portion of the exhaust tube; and a local exhaust part provided in the sealing case to exhaust the inside of the sealing case.

The exhaust module may further include a leakage detection part provided in the sealing case to detect leakage of an exhaust gas of the exhaust tube.

The exhaust module may further include a connection part configured to connect the exhaust tube to the exhaust port of the process tube.

The connection part may include: a first flange provided in the process tube; a second flange provided at one end of the exhaust tube; and a sealing member provided between the first flange and the second flange.

The connection part may further include a bellows having flexibility.

The exhaust tube may include a first exhaust tube connected to the exhaust port to extend in a first direction, and the sealing case may include a first casing part configured to accommodate the first exhaust tube.

The system may further include a lower chamber provided below the process tube, wherein the exhaust tube may further include a second exhaust tube connected to the first exhaust tube to extend downward, and the sealing case may further include a second casing part spaced apart from the lower chamber and configured to accommodate the second exhaust tube.

The system may further include a substrate boat in which a plurality of substrates are loaded in in multiple stages and accommodated in the process tube.

The process tube may be provided in plurality to be arranged in a direction crossing the extension direction of the exhaust tube, and the exhaust module may be provided in each of the process tubes.

The exhaust tube of each of the exhaust modules may be provided side by side with each other.

The system may further include a plurality of gas supply modules respectively provided in the process tubes and disposed symmetrical to each other.

At least a portion of each of the exhaust modules may be disposed between the plurality of gas supply modules.

The plurality of gas supply modules and the exhaust module may be disposed at least partially side by side.

The exhaust module may further include a leakage gas dilution part connected to the local exhaust part to dilute a leaking exhaust gas.

### BRIEF DESCRIPTION OF THE DRAWINGS

Exemplary embodiments can be understood in more detail from the following description taken in conjunction with the accompanying drawings, in which:

FIG. 1 is a schematic perspective view of a system for processing a substrate in accordance with an exemplary embodiment;

FIG. 2 is a conceptual view for explaining a lower chamber in accordance with an exemplary embodiment;

FIG. 3 is a coupling perspective view of a dual system for processing a substrate in accordance with an exemplary embodiment; and

FIG. 4 is a plan view of the dual system for processing the substrate in accordance with an exemplary embodiment.

### DETAILED DESCRIPTION OF EMBODIMENTS

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

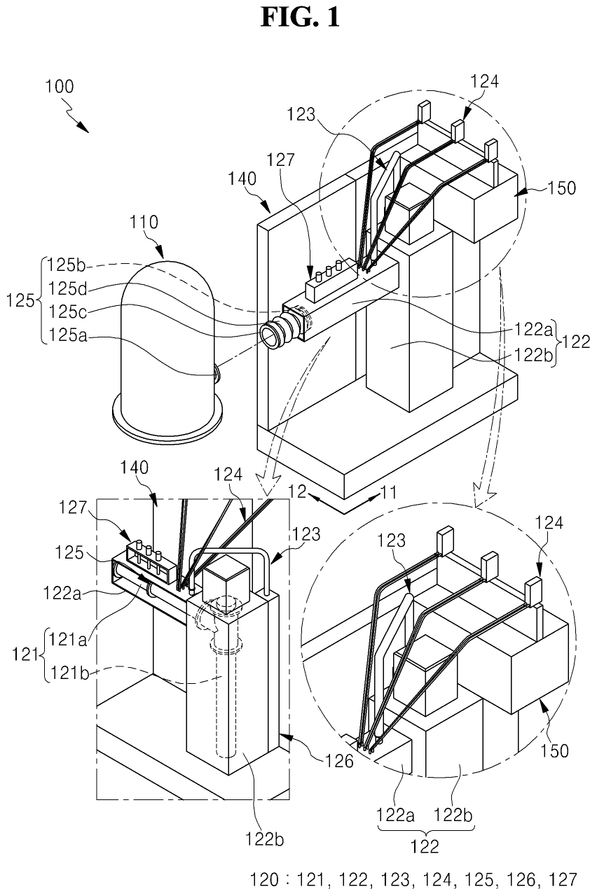

FIG. 1 is a schematic perspective view of a system for processing a substrate in accordance with an exemplary embodiment.

Referring to FIG. 1, a system 100 for processing a substrate in accordance with an exemplary embodiment includes a process tube 110 providing a processing space for a substrate 10 and an exhaust module 120 connected to an exhaust port 111 of the process tube 110 to exhaust process residues in the processing space to the outside.

The process tube 110 may provide the processing space for the substrate 10, and the processing process for a single or a plurality of substrates 10 may be performed in the processing space. For example, the process tube 110 may have a cylindrical shape with a closed upper portion and an opened lower portion and made of a heat resistance material such as quartz or ceramic. The plurality of substrates 10 may be accommodated to be processed in the process tube 110. Here, the processing space may be a space in which a substrate boat 115, on which the plurality of substrates 10 are laminated in a longitudinal direction of the process tube 110, are accommodated, and also, an actual processing process (for example, a deposition process) is performed.

An exhaust module 120 may be connected to the exhaust port 111 of the process tube 110 and exhaust the process residues in the processing space to the outside. For example, the exhaust tube 121 may communicate with the exhaust port 111 of the process tube 110. Thus, the process residues may be discharged from the processing space and may be exhausted to the outside.

Here, the exhaust module 120 includes the exhaust tube 121 connected to the exhaust port 111, a sealing case 122 that accommodates at least a portion of the exhaust tube 121, and a local exhaust part 123 provided in a sealing case 122 and exhaust the inside of the sealing case 122. The exhaust tube 121 may be connected to the exhaust port 111 and may provide a path through which the process residues are discharged from the processing space through the exhaust port 111 so that an exhaust gas containing the process residues is exhausted.

The sealing case 122 may accommodate at least a portion of the exhaust tube 121 and prevent the exhaust gas leaking from the exhaust tube 121 from escaping to an external environment (e.g., a work space of a semiconductor manufacturing facility (FAB). Thus, even if the exhaust gas leaks from the exhaust tube 121, an operator and/or device(s) in an external environment may be prevented from being affected or damaged by the leaking exhaust gas.

The local exhaust part 123 may be provided in the sealing case 122 and may exhaust the inside of the sealing case 122. For example, the local exhaust part 123 may exhaust the leaking exhaust gas from the inside of the sealing case 122 and may prevent the exhaust gas from being saturated in the sealing case 122. In addition, an outer wall of the exhaust tube 121 and/or an inner wall of the sealing case 122 may be prevented from being damaged by the leaking exhaust gas. In addition, the leaking exhaust gas may be exhausted and removed from the sealing case 122, and thus, a portion at which leakage occurs may be maintained. Here, after the leaking exhaust gas is completely removed from the inside of the sealing case 122, the sealing case 122 is opened, and then, the exhaust tube 121, in which the leakage occurs, inside the sealing case 122, and the connection part 125 may be maintained. The local exhaust part 123 may exhaust the inside of the sealing case 122 to maintain the inside of the sealing case 122 in a vacuum state, and an internal pressure (or atmospheric pressure) of the sealing case 122 may be maintained to be low so as to fundamentally block the leakage of the gas itself from the inside to the outside of the sealing case 122.

In the system 100 for processing the substrate, chemicals that are toxic, flammable, corrosive, delayed, etc., and are harmful to the human body may be used as process gases for processing the substrate, and also, chemicals (e.g., DCS, NH₃, F₂, etc.) that are toxic may be contained in the process residues discharged to the exhaust tube 121. Thus, when the exhaust gas containing the process residues leaks from the exhaust tube 121 to escape to the external environment, a safety accident due to the chemicals may occur. In addition, when the exhaust gas leaks, not only the exhaust gas may be harmful to the human body, but also tens or hundreds of devices in a semiconductor manufacturing facility (FAB) have to be shut down. Therefore, even if the exhaust gas leaks from the exhaust tube 121, it is important to prevent the leaking exhaust gas from escaping to the external environment.

Therefore, in the system 100 for processing the substrate in accordance with an exemplary embodiment, the exhaust tube 121 may be cased using the sealing case 122, the inside of the sealing case 122 may be exhausted through the local exhaust part 123 to prevent the exhaust gas from leaking to the external environment even if the leakage occurs in the exhaust tube 121, the connection part 125, and the like. Therefore, the safety accidents due to the chemicals contained in the exhaust gas may be prevented from occurring, and the shutdown of all of the devices in the semiconductor manufacturing facility (FAB) due to the leakage of the exhaust gas may be prevented.

In addition, the exhaust module 120 may further include a leakage detection part 124 provided in the sealing case 122 to detect the leakage of the exhaust gas of the exhaust tube 121. The leakage detection part 124 may be provided in the sealing case 122 and may sense whether the exhaust gas leaks from the exhaust tube 121. For example, the leakage detection part 124 may detect the leaking exhaust gas by directly detecting the exhaust gas and detect the leakage of the exhaust gas by measuring (or sensing) a change in internal pressure of the sealing case 122. Thus, the exhaust gas leaking from the exhaust tube 121 may be effectively removed immediately after the leakage occurs. In addition, an occurrence of a gap in the exhaust tube 121 and the connection part 125 may be detected to stop an operation of only the process tube 110 to which the exhaust tube 121 and/or the connection part 125, in which the leakage occurs, are connected, thereby maintaining the exhaust tube 121 and/or the connection part 125, in which the leakage occurs, so that the system 100 for processing the substrate does not continue to operate in the state in which the exhaust gas is leaking.

That is, in the system 100 for processing the substrate in accordance with an exemplary embodiment, the leakage detection part 124 may be provided in the sealing case 122 to detect the leakage of the exhaust gas. Thus, the exhaust gas leaking from the exhaust tube 121 may be effectively removed immediately when the leakage occurs, and also, the occurrence of the gap in the exhaust tube 121 and/or the connection part 125 may be detected to maintain the exhaust tube 121 and/or the connection part 125 so that the system 100 for processing the substrate does not continue to operate in the state in which the exhaust gas is leaking.

In addition, the exhaust module 120 may further include the connection part 125 connecting the exhaust tube 121 to the exhaust port 111 of the process tube 110. The connection part 125 may connect one end of the exhaust tube 121 to the exhaust port 111 of the process tube 110 and may seal a gap between the one end of the exhaust tube 121 and the exhaust port 111 of the process tube 110. For example, the connection part 125 may include a sealing member 125c such as an O-ring for sealing.

The system 100 for processing the substrate in accordance with an exemplary embodiment may further include a heater (not shown) provided in the process tube 110 to supply thermal energy to the process tube 110.

A heater (not shown) may be provided in the process tube 110 and may supply thermal energy (or heat) to the process tube 110. For example, the heater (not shown) may be provided outside the process tube 110 and may accommodate and heat the process tube 110. Thus, a temperature of the plurality of substrates 10 accommodated in the process tube 110 may be raised to a temperature capable of processing (or reacting) the substrate.

In the system 100 for processing the substrate, since the process tube 110 is heated to a high temperature for the substrate processing, the heat may be transferred to the connection part 125, and thus, the sealing member 125c may be deformed or damaged by the heat. As a result, a gap may occur in the connection part 125, and thus, the exhaust gas may leak through the gap. In addition, since the sealing member 125c is made of a flexible material so as to be in close contact with the exhaust port 111 and/or the exhaust tube 121 of the process tube 110 for sealing, even when the sealing member 125c is used for a long time, the sealing member 125c may be deformed or damaged to generate the gap.

When the exhaust tube 121 is provided in plurality, the connection part 125 may also be provided between the exhaust tubes 121. The connection part 125 provided between the exhaust tubes 121 may also include the sealing member 125c for the sealing, which may also be deformed and/or damaged by the prolonged use and/or heat to generate a gap, and thus, the leakage of the exhaust gas may occur due to the gap.

The connection part 125 includes a first flange 125a provided in the process tube 110, a second flange 125b provided on one end of the exhaust tube 121, and the sealing member 125c provided between the first flange 125a and the second flange 125b. The first flange 125a may be provided in the process tube 110 and may be provided at a lower end of the process tube 110 to form the exhaust port 111. Here, the first flange 125a may be made of quartz or ceramic in the same manner as the process tube 110.

The second flange 125b may be provided at one end of the exhaust tube 121 and may be connected to the first flange 125a to allow the exhaust port 111 and the exhaust tube 121 to communicate with each other. Here, the second flange 125b may be made of the same material as the exhaust tube 121 and may be made of a metal material having corrosion resistance.

The sealing member 125c may be provided between the first flange 125a and the second flange 125b and be in close contact with each of the first flange 125a and the second flange 125b to seal a gap between the first flange 125a. and the second flange 125b.

The connection part 125 may further include a bellows 125d having elasticity or variable length. The bellows 125d may have a variable length and may seal the gap between the first flange 125a and the second flange 125b. Also, the bellows 125d may allow the first flange 125a and the second flange 125b from being spaced apart from each other by a safety distance or more so that the first flange 125a and the second flange 125b are not impacted again each other.

Since the first flange 125a and the second flange 125b are made of different materials (e.g., quartz and a metal material), at least one of the first and second flanges 125a and 125b may be damaged when being in close contact with each other to be pressed or colliding with each other. For example, the second flange 125b made of a metal material is relatively stronger than the first flange 125a made of quartz. As a result, when the second flange 125b collides with the first flange 125a, or a pressure is applied to the first flange 125a, the first flange 125a may be damaged, such as being broken. Thus, the first flange 125a and the second flange 125b may be spaced apart from each other by the safety distance or more through the bellows 125d, and the first flange 125a and the second flange 125b may be sealed. Here, the exhaust tubes 121 made of different materials may be frequently coupled to and separated from the exhaust port of the process tube 110 so as to maintain the process tube 110 and the exhaust module 120. Here, the bellows 125d may prevent the first flange 125a and the second flange 125b, which are made of different materials, from being damaged due to collision and pressing by being coupled to each other.

When the connection part 125 includes the bellows 125d, particles may be generated from an outer wall of the bellows 125d as the bellows 125d is stretched or changed (in length), and also, the bellows 125d may be deformed and/or damaged by prolonged use and/or heat to generate a gap. In the system 100 for processing the substrate in accordance with an exemplary embodiment, the particles generated from the outer wall of the bellows 125d may be prevented from leaking to the external environment through the sealing case 122 and/or the local exhaust part 123, and also, the exhaust gas leaking through the gap generated by the prolonged use and/or heat may be prevented from leaking to the external environment.

When the exhaust port 111 of the process tube 110 and the exhaust tube 121 and/or the exhaust tubes 121 are coupled (or re-coupled) due to an initial installation of the system 100 for processing the substrate and/or re-installation after maintenance of the process tube 110, the exhaust tube 121, the connection part 125, and the like, whether leakage occurs in the connection part 125 between the exhaust port 111 of the process tube 110 and the exhaust tube 121 and/or between the exhaust tubes 121 has to be inspected. In this case, in the system 100 for processing the substrate in accordance with an exemplary embodiment, the leakage may be effectively inspected through the sealing case 122 and the leakage detection part 124, and even when the leakage occurs due to defective coupling, the leaking exhaust gas may be effectively removed (or exhausted) through the local exhaust part 123 without the leakage of the exhaust gas to the external environment. Here, while the process proceeds in a state of omitting a separate inspection, and the leakage of the exhaust gas may be detected.

When cooling is performed to prevent deformation by heat of the sealing member 125c, while the exhaust gas is cooled on a surface of the sealing member 125c, the particles may be attached to the surface of the sealing member 125c, and thus, the particles may affect the exhaust or the processing process. Thus, the sealing member 125c may not be cooled, and even if the sealing member 125c is cooled, it is difficult to install a configuration for cooling because a space is narrow. Thus, it is necessary to detect the leakage of the exhaust gas from the connection part 125, effectively remove the leaking exhaust gas, and maintain the leaking connection part 125. Thus, in this embodiment, the exhaust tube 121 and the connection part 125 may be cased using the sealing case 122, and the inside of the sealing case 122 may be exhausted through the local exhaust part 123 to prevent the exhaust gas from leaking to the external environment even if the leakage occurs in the exhaust tube 121, the connection part 125, and the like.

Here, the exhaust tube 121 may include a first exhaust tube 121a connected to the exhaust port 111 to extend in a first direction 11. The first exhaust tube 121a may be connected to the exhaust port 111 to extend in the first direction 11, and at least a portion of the first exhaust tube 121a may be accommodated in the sealing case 122. Here, the first exhaust tube 121a may be provided horizontally and may be a portion having only a straight section. In this case, the exhaust tube 121 may be provided in a straight line without being bent at the exhaust port 111, and thus, the exhaust tube 121 may have a structure having the straightness rather than the curved shape to improve exhaust performance of the process tube 110.

If the exhaust tube 121 is bent, the exhaust performance may be deteriorated depending on the number of bending of the exhaust tube 121, and the first exhaust tube 121a may be provided horizontally in a straight line to prevent the exhaust performance from being deteriorated, and exhaust performance of the process tube 110 may be ensured. Thus, the horizontal section of the exhaust tube 121 including the first exhaust tube 121a may be provided in the straight line. When the horizontal section of the exhaust tube 121 is provided in the straight line, the exhaust tube 121 may have an inner diameter of approximately 50 mm or more (or a size of approximately 100 A or more), and thus the exhaust performance of the process tube 110 may be further improved. In this case, the inner diameter of the exhaust tube 121 may be less than a width of the process tube 110.

The sealing case 122 may include a first casing part 122a accommodating the first exhaust tube 121a. The first casing part 122a may accommodate the first exhaust tube 121a, and at least one end of the first exhaust tube 121a connected to the exhaust port 111 and the connection part 125 may be accommodated in the first casing part 122a. Thus, the casing may be performed so that a gap between the exhaust port 111 of the process tube 110 in which the leakage of the exhaust gas frequently occurs and one end of the exhaust tube 121 is not exposed to the outside. Thus, even if the exhaust gas leaks in this portion (e.g., the connection part, etc.), the exhaust gas may be prevented from leaking to the external environment.

The exhaust module 120 may further include a vacuum sensor 127 connected to the exhaust tube 121 (e.g., to the first exhaust tube) to measure a vacuum degree of the process tube 110. The vacuum sensor 127 may be provided (or connected) to the exhaust tube 121 such as the first exhaust tube 121a and may measure the vacuum degree of the process tube 110. The vacuum sensor 127 has to be connected to the exhaust tube 121 to communicate with the exhaust tube 121 in order to measure the vacuum degree of the process tube 110. Thus, the connection part 125 may be provided also at a connection portion between the exhaust tube 121 and the vacuum sensor 127, and the leakage of the exhaust gas may occur between the exhaust tube 121 and the vacuum sensor 127 (for example, the connection part). Thus, the sealing case 122 may accommodate the connection portion between the exhaust tube 121 and the vacuum sensor 127.

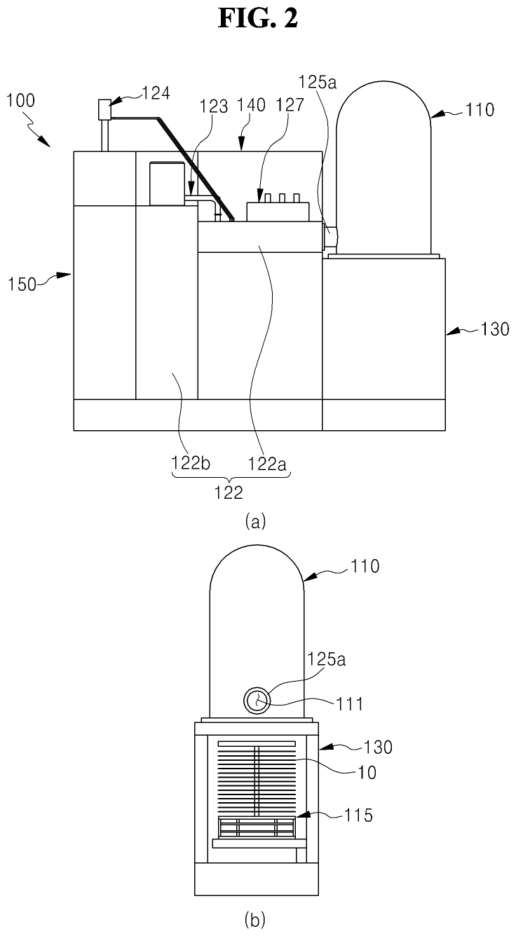

FIG. 2 is a conceptual view for explaining a lower chamber in accordance with an exemplary embodiment. Here, (a) of FIG. 2 illustrates a side view of the system for processing the substrate, and (b) of FIG. 2 illustrates a front view of the lower chamber.

Referring to FIG. 2, the system 100 for processing the substrate in accordance with an exemplary embodiment may further include a lower chamber 130 provided under the process tube 110.

The lower chamber 130 may be provided under the process tube 110 to provide a space in which a plurality of substrates 10 are loaded and stacked in multiple stages (or vertically) on the substrate boat 115. Here, the substrate boat 115 on which the plurality of substrates 10 are loaded in the lower chamber 130 may be elevated and accommodated in the processing space of the process tube 110 to perform the substrate processing process. For example, an upper portion of the lower chamber 130 may be opened so that the substrate boat 115 ascends and descends, and a passage through which the substrate 10 is accessible may be provided at one side so that the plurality of substrates 10 are loaded. Here, the lower chamber 130 may be connected to a transfer chamber (not shown) and may have a passage connected to the transfer chamber (not shown). The substrate 10 may be loaded from the transfer chamber (not shown) to the lower chamber through the passage. A gate valve (not shown) may be installed outside the passage, and the passage may be opened and closed by the gate valve (not shown).

The system 100 for processing the substrate in accordance with an exemplary embodiment may further include a substrate boat 115 in which the plurality of substrates 10 are laminated in multiple stages and accommodated in the process tube 110.

The plurality of substrates 10 may be loaded in multiple states and be accommodated in the process tube 110 to perform the substrate processing process. That is, in the substrate boat 115, the plurality of substrates 10 may be loaded in multiple stages to perform the substrate processing process in a batch type. Also, the substrate boat 115 may be provided in the processing space of the process tube 110, and when the substrate processing process is performed, the substrate boat 115 may be accommodated in the inner space (i.e., the processing space). Here, the substrate boat 115 may be provided in plurality and be respectively provided in the processing spaces of the plurality of process tubes 110. Here, the substrate boat 115 may have a plurality of independent spaces in which the plurality of substrates 10 are individually processed.

In addition, the exhaust tube 121 may further include a second exhaust tube 121b that is connected to the first exhaust tube 121a to extend downward. The second exhaust tube 121b may extend downward, be connected to the first exhaust tube 121a, be directly connected to the first exhaust tube 121a, or be connected through an additional exhaust tube 121 and/or a connection part 125. Even when the exhaust port 111 is disposed at a high position by the lower chamber 130 through the second exhaust tube 121b, the first exhaust tube 121a may be horizontal and have straightness.

In addition, when the exhaust tube 121 has an overhead structure because of having a horizontal section by the first exhaust tube 121a and a vertical section by the second exhaust tube 121b, the first exhaust tube 121a may be spaced apart from a bottom surface (or a downward facing surface) to provide a maintenance space between the first exhaust tube 121a and the bottom surface.

Here, the sealing case 122 may further include a second casing part 122b spaced apart from the lower chamber 130 and accommodating the second exhaust tube 121b. The second casing part 122b may accommodate the second exhaust tube 121b. Since the leakage of the exhaust gas may occur even in the second exhaust tube 121b and/or the connection part 125 that connects the second exhaust tube 121b to the other exhaust tube 121, the second exhaust tube 121b, the connection part 125, and the like may be cased so as not to be exposed to the outside. Thus, even if the leakage of the exhaust gas occurs in the second exhaust tube 121b, the connection part 125, and the like, the exhaust gas may be prevented from being leaking to the external environment.

In addition, the second casing part 122b may be spaced apart from the lower chamber 130 and may provide the maintenance space between the second casing part 122b and the lower chamber 130. In this case, the second casing part 122b may be disposed to face the lower chamber 130, and a maintenance port for maintenance of the second exhaust tube 121b and the like may be provided on a surface opposite to the lower chamber 130. When the second casing part 122b is disposed to face the lower chamber 130, the exhaust port 111 is provided at a center of the process tube 110 in the first direction 11, and the first exhaust tube 121a may be provided in a straight line in the first direction 11 so that the exhaust performance of the process tube 110 is maximized (or optimized). Also, when the second casing part 122b has the maintenance port, the maintenance of the second exhaust tube 121b and the like may be facilitated in the maintenance space between the lower chamber 130 and the second casing part 122b.

The system 100 for processing the substrate in accordance with an exemplary embodiment may further include a control module 150 provided in the first direction 11 of the second casing part 122b.

The control module 150 may be provided in the first direction 11 of the second casing part 122b and may control the substrate processing process performed in the process tube 110. For example, the control module 150 may control an operation of each of the exhaust module 120 and the gas supply module 140 to control the substrate processing process. Here, the control module 150 may be provided in the form of a control box, and the second casing part 122b may have the maintenance port for maintenance of the second exhaust tube 121b, and the like on the surface of the first direction 11. Here, the maintenance port may be opened and closed by the control module 150. For example, the control module 150 may be connected to the second casing part 122b through a hinge structure so as to be opened and closed. As a result, a surface of the second casing part 122b in the first direction 11 may be opened and closed.

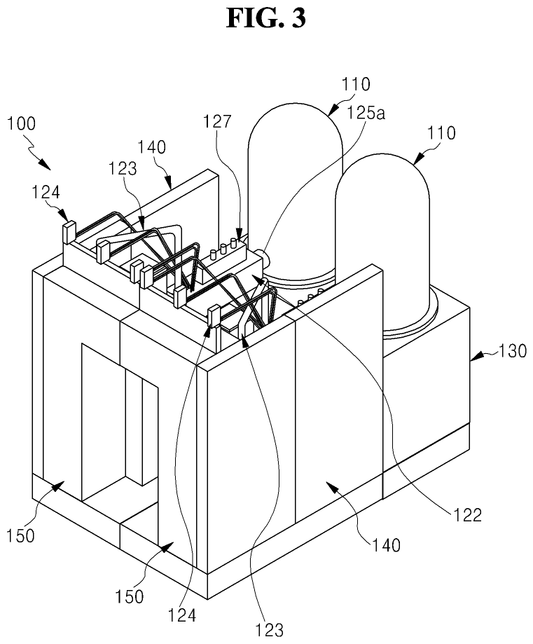

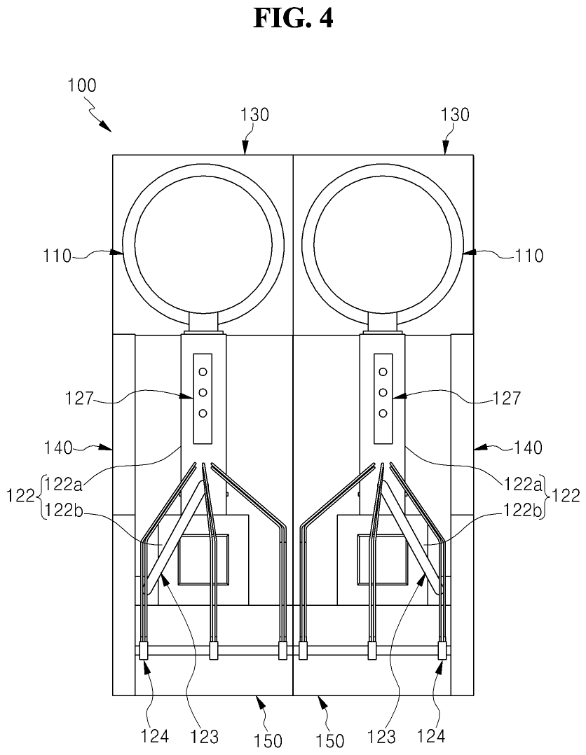

FIG. 3 is a coupling perspective view of a dual system for processing a substrate in accordance with an exemplary embodiment, and FIG. 4 is a plan view of the dual system for processing the substrate in accordance with an exemplary embodiment.

Referring to FIGS. 3 and 4, a process tube 110 may be provided in plurality to be arranged in a direction crossing an extension direction of an exhaust tube 121. For example, the exhaust tube 121 may extend in the first direction 11, and the plurality of process tubes 110 may be arranged in a second direction 12 crossing the first direction 11. The plurality of process tubes 110 may be disposed to be spaced apart from each other in the second direction 12 and be paired and also may provide process space that are independent of each other. Here, the second direction 12 may be a direction that is transverse to the system 100 for processing the substrate. Each of the plurality of process tubes 110 may have an internal space, a substrate boat 115 may be accommodated during a substrate processing process, and a gas atmosphere (or atmospheric gas), a temperature, and the like may be independently controlled. The plurality of process tubes 110 may be independently controlled so that the substrate processing process is stably performed, a substrate throughput and substrate processing quality through the system 100 for processing the substrate is improved, and a distance and/or surrounding arrangement of the plurality of process tubes 110 are reduced to reduce a foot print. Here, the plurality of process tubes 110 may be provided as a single tube or may be provided as a plurality of tubes. Here, it is sufficient if the substrate boat 115 is accommodated therein to provide a process space in which the substrate processing process is performed. For example, the plurality of process tubes 110 may include an outer tube and an inner tube.

Here, the exhaust module 120 may be provided in each of the process tubes 110. Since the exhaust module 120 is provided to each of the process tubes 110, exhaust of each process tube 110 may be separately controlled, and the substrate processing process of each process tube 110 may be independently controlled.

In this case, the exhaust tube 121 of each of the exhaust modules 120 may be provided side by side with each other. That is, the exhaust tubes 121 respectively provided to the exhaust modules 120 may be provided side by side to be provided in a straight line from the exhaust port 111 at a center of the process tube 110, and exhaust performance of the process tube 110 may be maximized. In addition, the exhaust tubes 121 may be symmetrical to each other so that a uniform substrate processing process is performed through uniform exhaust between the plurality of process tubes 110.

The system 100 for processing the substrate in accordance with an embodiment may further include a plurality of gas supply modules 140, which are respectively provided in the process tubes 110 and arranged symmetrical to each other.

The plurality of gas supply modules 140 may be provided to the process tube 110, respectively, and may be disposed symmetrical to each other. For example, the plurality of gas supply modules 140 may be respectively provided in the first direction 11 of the process tubes 110 and may be disposed symmetrical to each other with respect to a line extending in the first direction 11 from the center between the plurality of process tubes 110 (or a line extending in the first direction from the center between the plurality of process tubes 110). The plurality of gas supply modules 140 are provided symmetrical to each other in the first direction 11 of the process tubes 110 to control the gas supply of the process tubes 110, respectively. Here, the substrate processing process of each of the process tubes 110 may be independently controlled by controlling the gas supply of each of the process tubes 110, and uniform substrate processing process may be performed through uniform gas supply between the plurality of process tubes 110. Here, the plurality of gas supply modules 140 may be spaced apart from each other in the second direction 12 to provide a space therebetween, and the gas supply modules 140 and the process tubes 110, and the lime may be maintained in the space between the plurality of gas supply modules 140.

In the system 100 for processing the substrate in accordance with an exemplary embodiment, the substrate throughput may be improved through the plurality of process tubes 110 providing the processing spaces that are independent of each other. In addition, in the system 100 for processing the substrate, the plurality of gas supply modules 140 may be disposed symmetrical to each other in the first direction 11 of each of the process tubes 110 to provide the maintenance space in a space between the plurality of gas supply modules 140 and/or a spaced space between a sealing case 122 and each of the gas supply modules 140.

At least a portion of each exhaust module 120 may be disposed between the plurality of gas supply modules 140. For example, a first exhaust tube 121a of each exhaust module 120 may be disposed between the plurality of gas supply modules 140. That is, the plurality of gas supply modules 140 may be disposed symmetrically to deviate from both sides (or in a direction away from each other) from a line extending in the first direction 11 from a center of the corresponding process tube 110 (or a line extending in the first direction from the center of the corresponding process tube) of the plurality of process tubes 110.

When the plurality of gas supply modules 140 deviate from the line extending in the first direction 11 from the center of the corresponding process tube 110, the space between the plurality of gas supply modules 140 may be wider, and a wide maintenance space may be secured between the plurality of gas supply modules 140. For example, the plurality of gas supply modules 140 may be disposed to deviate from the line extending in the first direction 11 from the center of the corresponding process tube 110 by extending diagonally (or in a diagonal direction) from the corresponding process tube 110 (e.g., from the center of the corresponding process tube). In addition, the plurality of gas supply modules 140 may be disposed to deviate from the line extending in the first direction 11 from the center of the corresponding process tube 110 by extending to deviate in the second direction 12 from the center of the corresponding process tube 110.

In this case, the plurality of gas supply modules 140 and the exhaust module 120 may be disposed at least partially side by side. For example, the first exhaust tube 121a of the exhaust module 120 may be provided in a straight line in the first direction 11, and the plurality of gas supply modules 140 may also extend in the first direction 11 in parallel with the first exhaust tube 121a. When the plurality of gas supply modules 140 extend in the first direction 11, a width of the system 100 for processing the substrate in the second direction 12 may be minimized Here, the plurality of gas supply modules 140 may be disposed side by side at both ends of the plurality of process tubes 110 in the first direction 11 and may be disposed side by side to extend in the first direction 11 from both ends of a process part (or a process region) in which the plurality of process tubes 110 are disposed. In this case, a width of the system 100 for processing the substrate in the second direction 12 may be minimized, and thus, the maintenance space may be maximized. In addition, for a laminar flow of the process gas, the plurality of gas supply modules 140 have to supply the process gas in a direction opposite to the exhaust port 111 of the process tube 110. Here, when the plurality of gas supply modules 140 are arranged side by side at both ends of the system 100 for processing the substrate in the second direction 12, the number of bending and/or bending distance of the gas supply line may be reduced and minimized. In addition, since the plurality of gas supply modules 140 may not interfere with the exhaust module 120 such as the exhaust tube 121, the plurality of gas supply modules 140 may be provided as close as possible to each process tube 110, respectively. Thus, a length of the gas supply line may be shortened, and thus, a gas supply time may be shortened, and gas supply performance may be improved.

Each of the plurality of gas supply modules 140 may be provided in a lower portion of a sealing case 122 (that is, a lower portion of a first casing part) to provide a spaced space that is spaced apart from the sealing case 122 (or a spaced space that is spaced apart from the first casing part). The maintenance space may be provided in the spaced space between the plurality of gas supply modules 140 and the first casing part 122a to perform the maintenance of the gas supply module 140, the exhaust module 120, and the process tube 110.

The exhaust module 120 may further include a leakage gas dilution part 126 connected to a local exhaust part 123 to dilute a leaking exhaust gas. The leakage gas dilution part 126 may be connected to the local exhaust part 123 to dilute the leaking exhaust gas and also dilute a toxic gas contained in the leaking exhaust gas to be discharged to the outside. For example, after collecting the leaking exhaust gas in a predetermined space, the collected exhaust gas may be diluted with nitrogen (N2) or the like to discharge the exhaust gas to the outside in a nontoxic state.

As described above, in this embodiment, the exhaust tube may be cased using the sealing case, and the inside of the sealing case may be exhausted through the local exhaust part, and thus, even if the leakage occurs in the exhaust tube, the leakage of the exhaust gas to the outside may be prevented. Therefore, the safety accidents due to the chemicals contained in the exhaust gas may be prevented from occurring, and the shutdown of the all devices in the semiconductor manufacturing facility (FAB) due to the leakage of the exhaust gas may be prevented. In addition, the leakage detection part may be provided in the sealing case to detect the leakage of the exhaust gas, thereby effectively removing the exhaust gas leaking from the exhaust tube, and also, to detect the occurrence of the gap in the exhaust tube and/or the connection part, thereby maintaining the exhaust tube and/or the connection part so that the system for processing the substrate does not continue to operate in the state in which the exhaust gas is leaking. In addition, the substrate throughput may be improved through the plurality of process tubes that provide the processing spaces that are independent of each other, and the plurality of gas supply modules may be symmetrically disposed in the first direction of each of the process tubes to provide the maintenance space in the space between the plurality of gas supply modules and/or the spaced space between the sealing case and the gas supply module. The exhaust tubes made of different materials may be frequently coupled to and separated from the exhaust port of the process tube so as to maintain the process tube and the exhaust module. Here, the bellows may be provided between the exhaust port and the exhaust tube of the process tube to prevent the exhaust port and the exhaust tube of the process tube, which are made of different materials, from colliding with each other, and the exhaust port and/or the exhaust tube of the process tube may be prevented from being damaged due to the pressurization.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

In the system for processing the substrate in accordance with the exemplary embodiment, the exhaust tube may be cased using the sealing case, and the inside of the sealing case may be exhausted through the local exhaust part, and thus, even if the leakage occurs in the exhaust tube, the leakage of the exhaust gas to the outside may be prevented. Therefore, the safety accidents due to the chemicals contained in the exhaust gas may be prevented from occurring, and the shutdown of the all devices in the semiconductor manufacturing facility (FAB) due to the leakage of the exhaust gas may be prevented.

In addition, the leakage detection part may be provided in the sealing case to detect the leakage of the exhaust gas, thereby effectively removing the exhaust gas leaking from the exhaust tube, and also, to detect the occurrence of the gap in the exhaust tube and/or the connection part, thereby maintaining the exhaust tube and/or the connection part so that the system for processing the substrate does not continue to operate in the state in which the exhaust gas is leaking.

In addition, the substrate throughput may be improved through the plurality of process tubes that provide the processing spaces that are independent of each other, and the plurality of gas supply modules may be symmetrically disposed in the first direction of each of the process tubes to provide the maintenance space in the space between the plurality of gas supply modules and/or the spaced space between the sealing case and the gas supply module.

The exhaust tubes made of different materials may be frequently coupled to and separated from the exhaust port of the process tube so as to maintain the process tube and the exhaust module. Here, the bellows may be provided between the exhaust port and the exhaust tube of the process tube to prevent the exhaust port and the exhaust tube of the process tube, which are made of different materials, from colliding with each other, and the exhaust port and/or the exhaust tube of the process tube may be prevented from being damaged due to the pressurization.

Although the system for processing the substrate has been described with reference to the specific embodiments, it is not limited thereto. Therefore, it will be readily understood by those skilled in the art that various modifications and changes can be made thereto without departing from the spirit and scope of the present inventive concept defined by the appended claims.

What is claimed is:

1. A system for processing a substrate, the system comprising:
a process tube configured to provide a processing space for the substrate; and
an exhaust module connected to an exhaust port of the process tube to exhaust process residues within the processing space to the outside,
wherein the exhaust module comprises:
an exhaust tube connected to the exhaust port;
a sealing case configured to accommodate at least a portion of the exhaust tube; and
a local exhaust part provided in the sealing case to exhaust the inside of the sealing case.

2. The system of claim 1, wherein the exhaust module further comprises a leakage detection part provided in the sealing case to detect leakage of an exhaust gas of the exhaust tube.

3. The system of claim 1, wherein the exhaust module further comprises a connection part configured to connect the exhaust tube to the exhaust port of the process tube.

4. The system of claim 3, wherein the connection part comprises:
a first flange provided in the process tube;
a second flange provided at one end of the exhaust tube; and
a sealing member provided between the first flange and the second flange.

5. The system of claim 4, wherein the connection part further comprises a bellows having flexibility.

6. The system of claim 1, wherein the exhaust tube comprises a first exhaust tube connected to the exhaust port to extend in a first direction, and
the sealing case comprises a first casing part configured to accommodate the first exhaust tube.

7. The system of claim 6, further comprising a lower chamber provided below the process tube,
wherein the exhaust tube further comprises a second exhaust tube connected to the first exhaust tube to extend downward, and
the sealing case further comprises a second casing part spaced apart from the lower chamber and configured to accommodate the second exhaust tube.

8. The system of claim 1, further comprising a substrate boat in which a plurality of substrates is loaded in in multiple stages and accommodated in the process tube.

9. The system of claim 1, wherein the process tube is provided in plurality to be arranged in a direction crossing the extension direction of the exhaust tube, and
the exhaust module is provided in each of the process tubes.

10. The system of claim 9, wherein the exhaust tube of each of the exhaust modules is provided side by side with each other.

11. The system of claim 9, further comprising a plurality of gas supply modules respectively provided in the process tubes and disposed symmetrical to each other.

12. The system of claim 11, wherein at least a portion of each of the exhaust modules is disposed between the plurality of gas supply modules.

13. The system of claim 11, wherein the plurality of gas supply modules and the exhaust module are disposed at least partially side by side.

14. The system of claim 1, wherein the exhaust module further comprises a leakage gas dilution part connected to the local exhaust part to dilute a leaking exhaust gas.
